(19) United States
(12) Patent Application Publication
(10) Pub. No.: US 2023/0016486 A1
(43) Pub. Date: Jan. 19, 2023

(54) LOW-COST SURFACE MOUNT EMI GASKETS

(71) Applicant: Intel Corporation, Santa Clara, CA (US)

(72) Inventors: Dong-Ho Han, Beaverton, OR (US); Bala Subramanya, Bangalore K (IN); Greeshmaja Govind, Malappuram (IN); Sun Ye E, Bayan Lepas (MY); Boon Ping Koh, Seberang Jaya (MY); Juha Paavola, Hillsboro, OR (US); Kerry Stevens, Beaverton, OR (US); Neil Delaplane, Tigard, OR (US); Quek Liang Wee, Bayan Lepas (MY)

(21) Appl. No.: 17/956,486

(22) Filed: Sep. 29, 2022

(51) Int. Cl. H01L 23/552; H01L 25/065; H01L 23/367; H01L 21/48

(52) U.S. Cl. CPC H01L 23/552; H01L 25/0655; H01L 23/367; H01L 21/4875; H01L 24/32

(57) ABSTRACT

Electrically conductive compressible gaskets can be employed to ground a heat solution and provide electromagnetic interference (EMI) shielding. A plurality of gaskets may be arranged around the perimeter of an integrated circuit package such as a processor or system on a chip. Each of the gaskets is in contact with a ground plane in the package, and upon contact with a heat sink or cold plate, creates an electrical path that grounds the heat sink or cold plate and thereby minimizes the emission of spurious radio signals. Other embodiments may be described and/or claimed.

### TECHNICAL FIELD

Disclosed embodiments are directed to mitigation of electromagnetic interference, and specifically to compressible conductive electromagnetic interference (EMI) gaskets that can be attached to an integrated circuit package using surface-mount techniques.

### BACKGROUND

Most computing devices, despite advances in power management strategies and die size, still generate significant amounts of heat. High performance processors, Systems on Chips (SoCs), and graphics processors may each radiate over 100 Watts of heat. Such significant heat energy, if not properly dissipated, could damage the processor and/or require severe throttling of processor speed to keep die temperatures at an acceptable level. Furthermore, a typical computing device may have multiple components that generate heat besides the processor, such as graphics processors, memory controllers, and supporting circuitry, to name a few examples. Long-term, excessive heat can shorten device lifespan by causing premature component failure, and, in the case of portable and mobile devices, may make the device uncomfortably hot in use. Accordingly, a variety of approaches to absorb and dissipate heat away from a computing device's processor and supporting chips have been developed to allow a computing device to achieve its peak rated performance while keeping components below rated maximum temperatures.

The background description provided herein is for the purpose of generally presenting the context of the disclosure. Unless otherwise indicated herein, the materials described in this section are not prior art to the claims in this application and are not admitted to be prior art by inclusion in this section.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is an overhead view of a first example integrated circuit package with a plurality of compressible EMI gaskets, according to various embodiments.

FIG. 1B is an overhead view of a second example integrated circuit package with a plurality of compressible EMI gaskets, according to various embodiments.

FIG. 1C is an overhead view of a third example integrated circuit package with a plurality of compressible EMI gaskets, according to various embodiments.

FIG. 2A is a side cross-sectional view of an example integrated circuit package showing the arrangement of compressible EMI gaskets with respect to several package layers, according to various embodiments.

FIG. 2B is a side cross-sectional view of the example package of FIG. 2A, showing the EMI gaskets compressed with a cold plate, according to various embodiments.

FIG. 2C is a side cross-sectional view of the example package of FIG. 2A, showing a cold plate with recesses into which the EMI gaskets may fit, according to various embodiments.

FIG. 3 is an exploded perspective view of an example integrated circuit package and associated heat pipe with cold plate, according to various embodiments.

FIG. 4 is a process flow of an example method for fabricating an integrated circuit package with compressible EMI gaskets and a cold plate, according to various embodiments.

### DETAILED DESCRIPTION

In the following detailed description, reference is made to the accompanying drawings which form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Aspects of the disclosure are disclosed in the accompanying description. Alternate embodiments of the present disclosure and their equivalents may be devised without parting from the spirit or scope of the present disclosure. It should be noted that like elements disclosed below are indicated by like reference numbers in the drawings.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

Passing a varying or alternating current through a line can result in the emission of radio frequency (RF) energy, with the frequency of the RF energy emissions corresponding to the frequency of the current passing through the line, the emissions being enhanced when the line length is some multiple of the frequency wavelength. This is the basic principle by which antennas work for the transmission of radio signals. Consequently, as system clock speeds increase, various traces and similar connections used to tie together various components of an integrated circuit package may act as radiators for RF energy, depending upon their lengths. When clock speeds reach into the gigahertz range, the radiated RF energy likewise reaches into the gigahertz range.

Modern computer systems, whether desktop, laptop, or mobile, may be equipped with a number of different radios for wireless communications. Such radios may include Bluetooth and Bluetooth LE radios, WiFi radios, cellular radios, and NFC radios, to list a few of the more common radios equipped to modern computers. These various radios may operate in the gigahertz range of RF frequencies as required by their various standards and specifications. For example WiFi typically operates at 2.4 GHz, 5 GHz, and 5.8 GHz bands. Consequently, when a processor or other integrated circuit in the computer operates in the gigahertz frequency range, various connections within the package may radiate RF energy that potentially overlaps with the operating frequencies of one or more different radios equipped to the computer. These spurious emissions, if not contained or controlled, may interfere with the operation of the computer's various radios.

An effective way to prevent spurious emissions is to enclose the potentially radiating connectors in what is essentially a Faraday cage. A typical integrated circuit package, such as may comprise a computer system's processor, memory package, or system on a chip (SoC), includes a ground plane as part of the package. The top of the package is typically left open, with the various dies under exposed metallic covers to allow for the positioning of a heat sink or cold plate and heat pipe. The cold plate or heat sink, in turn, is typically contacted to the metallic covers of the dies using a thermally conductive interface material such as thermal paste or heat sink grease. This interface material may not be electrically conductive, however, and even if it is, the structures contacted by the cold plate or heat sink may not themselves be tied to ground. Consequently, the cold plate or heat sink, which may be metallic, may not be grounded. When not grounded, the cold plate or heat sink cannot form an effective shield against spurious RF emissions from the integrated circuit package.

Disclosed embodiments include compressible, electrically conductive gaskets for helping to mitigate spurious RF emissions. The disclosed gaskets are placed in contact with a ground plane of an integrated circuit. In turn, a cold plate or heat sink is placed on top of the gaskets, which are then compressed as the cold plate or heat sink is secured to an appropriate pressure to ensure proper thermal conductivity with the integrated circuit. As the gaskets are electrically conductive, they act to tie the heat sink or cold plate, which is metallic, to the ground plane of the integrated circuit. Thus, the integrated circuit and heat sink/cold plate are held at the same potential, and effectively act as a Faraday cage to dissipate or eliminate spurious RF emissions. The gaskets are compressible to ensure a good contact while also allowing the cold plate or heat sink to correctly contact the integrated circuit dies.

Furthermore, the electrically conductive compressible gaskets may be sized and equipped to be bonded to the integrated circuit ground plane using industry-standard SMT techniques. The gaskets may include a foil surface to accept solder, and so may be attached to the ground plane using solder reflow techniques, potentially at the same time and in the same process as used to attach other SMT components to the integrated circuit package. Other embodiments may be disclosed herein.

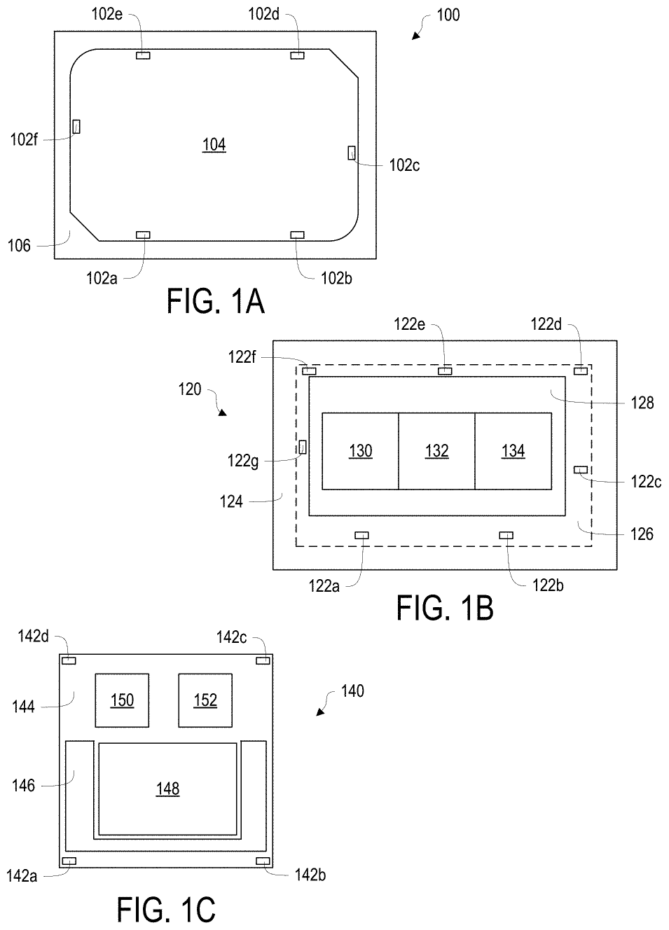

FIGS. 1A-1C illustrate several example arrangements of electrically conductive compressible gaskets on different integrated circuit packages, according to some possible embodiments. FIG. 1A depicts a first package 100, which includes gaskets 102a to 102e (collectively or generically, gasket 102) arranged around a perimeter of the package 100. Each of the gaskets 102 is disposed upon a substrate 104 that comprises a ground plane for the package 100. As each of the gaskets 102 is electrically conductive, each gasket 102 is tied to the potential of the substrate 104. Surrounding the gaskets 102 and running around the outer perimeter of the package 100 is a stiffener 106, which may be necessary depending upon the needs of a specific embodiment. Although not illustrated, the substrate 104 may include one or more dies that rise above the surface of the substrate. In other implementations, the die(s) may be embedded within the substrate 104.

FIG. 1B illustrates a second package 120, which includes gaskets 122a to 122g (collectively or generically, gasket 122) arranged around a perimeter of the package 120. In contrast to first package 100, second package 120 does not have a stiffener. The gaskets 122 are disposed upon a substrate 124 that comprises a ground plane for package 120. Although lacking a stiffener, substrate 124 includes a gasket permissible region 126, inset from the edge of the package 120. The setback of the gasket permissible region 126 provides a handling region that is clear of structures so that the package 120 can be positioned for installation without risk of damage. The gasket permissible region 126, in the depicted embodiment, may be from 3-5 mm in width. Inwards from the gasket permissible region 126 is an epoxy keep-out zone 128, within which several dies 130, 132, and 134 may be present. The dies 130, 132, and 134 are illustrated for example purposes only. It should be understood that more or fewer dies may be present, and in different sizes and configurations.

FIG. 1C illustrates a third package 140, which includes gaskets 142a to 142d (collectively or generically, gasket 142) disposed on a substrate 144, arranged with one gasket 142 proximate to each corner of the package 140. Package 140 includes a stiffener 146 that covers part of the substrate 144, and is located inboard from the gaskets 142. Also illustrated are a die 148, which may be a processor such as a System on a Chip (SoC), along with two dies 150 and 152, which may be DRAM or another type of memory module, associated with the SoC processor.

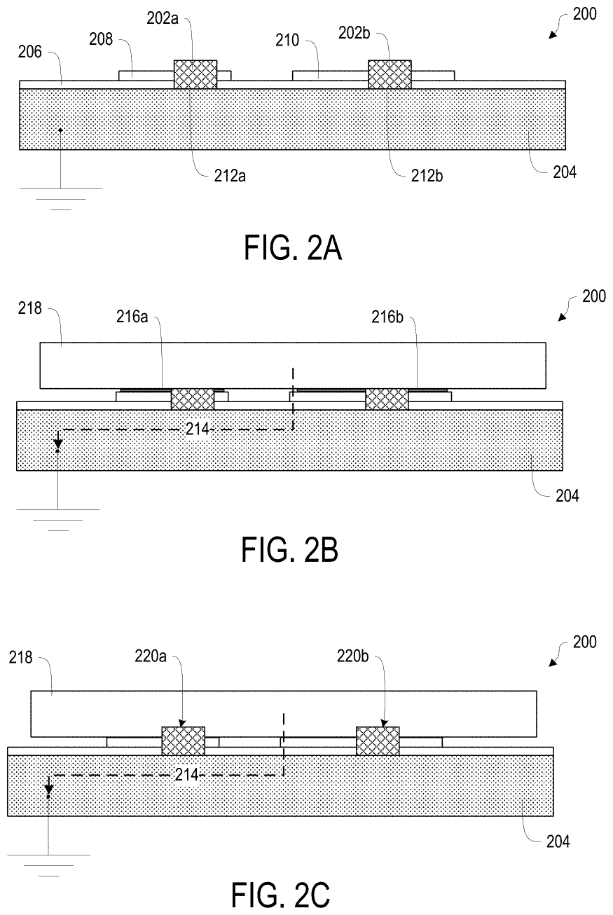

In each of FIGS. 1A-1C, the substrate 104, 124, 144 may be any material suitable for the fabrication of an integrated circuit package, and so may be selected with regard to the intended application of a given package. The substrate may be electrically conductive or may embed or include an electrically conductive layer that can be coupled to a system ground, to pull the layer to ground potential. As will be discussed below with respect to FIGS. 2A-2C, each of the various gaskets 102, 122, 142 sits upon a portion of the substrate that is coupled to ground potential, whether the substrate itself or an exposed layer.

In embodiments, the gaskets 102, 122, 142 may be cubic or rectangular in shape. In some embodiments, the dimensions of each gasket is at or around 1 mm in width, 0.5 mm in length, and 0.4-0.5 mm in height, and compression of each gasket by an installed cold plate or heat sink may be between 16% to 52% of height (e.g. compressed so that height is reduced by 16% to 52% from uncompressed). These dimensions may vary depending upon the material used to fabricate each gasket, and the needs of a given embodiment. For example, where material is used that is easily compressible, e.g. does not present substantial resistance or back pressure when compressed, the gaskets may be made larger, or more gaskets (greater number) put in place. In some embodiments, the gaskets may be formed as a ring of material that completely or nearly completely encloses the dies and forms a seal between the heat sink or cold plate and substrate that lacks any gaps.

The number of gaskets can impact RF shielding performance. Compared to a base line of no gaskets, increasing numbers of gaskets can result in increased shielding effectiveness, up to approximately six gaskets. Four gaskets, similar to the embodiment of package 140, shows marked improvement over no gaskets, while going to six gaskets further improves RF shielding over four gaskets. Increasing past six gaskets, for typical integrated circuit packages, shows diminishing returns in shielding improvement.

FIGS. 2A-2C illustrate the arrangement of electrically conductive compressible gaskets on a package 200 in a cross-sectional view. In FIG. 2A, package 200 is illustrated without a heat solution, such as a cold plate or heat sink, in place. Package 200 includes gaskets 202a and 202b (collectively or generically, gasket 202), which are disposed upon substrate 204. As can be seen, substrate 204 is tied to ground, indicated by the ground symbol. This may be accomplished by any suitable technique, including connecting the substrate 204 to one or more pins of the package that are connected to ground, by directly bonding or coupling the substrate 204 to a ground plane, such as by a grounding strap, a grounded fastener, or another suitable way of connecting the substrate 204 to a system or device ground.

Disposed upon and covering the top of substrate 204 may be a non-conductive or insulating layer 206, which can protect any connectors such as traces or microstrips that may be disposed on the top of the substrate 204. The insulating layer 206 may be any material suitable for a given implementation of package 200, such as varnish, lacquer, paint, epoxy, or another suitable insulating and/or protective coating. Also visible are two example dies 208 and 210, housing the integrated circuitry for package 200.

The insulating layer 206, in the depicted embodiment, includes a plurality of apertures 212a and 212b (collectively or generically, aperture 212), into which gaskets 202a and 202b are disposed, respectively. The apertures 212 expose a conductive portion of substrate 204 so that gaskets 202 can be placed in electrical communication with substrate 204, and brought to the same ground potential as substrate 204. The apertures 212 may be fabricated using any suitable technique, such as by masking the surface of the substrate 204 prior to application of the insulating layer 206, or by subsequent removal, either chemically or mechanically, of the substrate 204 to form the apertures 212 at the positions where the gaskets 202 will be disposed.

Each gasket 202, in embodiments, is fabricated from a compressible and electrically conductive material. Any suitable material that provides sufficient compressibility and is or can be made electrically conductive may be utilized. For example, the gaskets may be manufactured from a foam sponge that may be comprised of a conductive material or impregnated with conductive material such as graphite or metal particles. In other embodiments, the gaskets may be fabricated from a metallic or metalized foam. Any suitable material now known or later developed that can be compressed and provide electrical conductivity may be used, and the choice of material or materials may depend upon the particulars of a given implementation. The material may be selected to have sufficient resiliency to withstand compression from a cold plate while still maintaining a positive contact with the cold plate, despite possible changes in dimensions due to thermal heating and cooling cycles present in processor operation. In embodiments, each gasket provides a path from a cold plate or heat sink to the grounded substrate of less than 0.5 ohms.

Each gasket 202 may further include a foil layer disposed on the side that is received into the aperture 212. Gasket 202 may be soldered onto the substrate 204, and the foil layer may assist in adhesion of the solder to the gasket 202, to secure it to the substrate 204. Gaskets 202 may be sized comparable to surface mount components such as capacitors and resistors, and likewise can be adhered to the substrate 204 using standard solder techniques employed in surface mount electronics, such as using a solder paste and oven, solder reflow techniques, or another suitable technique now known or later developed.

FIG. 2B illustrates an embodiment of the package 200 with a heat sink or cold plate 218 secured onto the package 200. As can be seen, the cold plate 218 is in contact with each die 208, 210, and so has compressed each gasket 202, which are noticeably shorter than depicted in FIG. 2A. The compressed gaskets 202, being electrically conductive, this provide a low resistance path to ground 214, as shown. This low resistance path thus acts to dissipate any currents induced in the cold plate 218 from RF energy emitted by traces and other structures on or within the package 200, and so substantially prevent their transmission beyond the package 200 where they might otherwise interfere with the operation of various radios, as discussed above. Each gasket 202 may, in embodiments, have a resistance less than 0.5 ohms. As illustrated in FIG. 2B the cold plate 218 does not directly contact each die 208, 210, but rather has a layer of thermal compound 216a, 216b placed between the exposed surface of each die 208, 210, and the contacting surface of the cold plate 218. The thermal compound 216 may be a thermally conductive paste or grease, as is known.

FIG. 2C illustrates an embodiment of the package 200 with a cold plate 218 that includes recesses 220a and 220b to each receive gasket 202a and 202b. These recesses 220 may be necessary or desirable depending upon the compressibility of the material used to implement gaskets 202, the pressure that must be applied to the dies 208, 210 to achieve a proper thermal coupling with the cold plate 218, and/or the construction of the cold plate 218 itself, which may be limited in the overall amount of pressure it can withstand without deformation. Recesses 220 may allow the compression of each gasket 202 to be somewhat lessened, reducing the overall pressure placed upon cold plate 218 following installation and helping to prevent deformation.

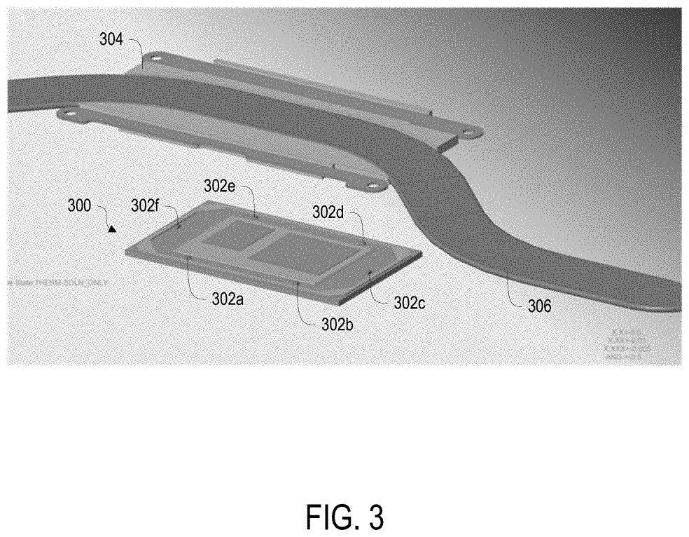

FIG. 3 illustrates an exploded view of a package 300 equipped with electrically conductive compressible gaskets 302a to 302f, over which a cold plate 304 attached to a heat pipe 306 may be placed. The layout of package 300 is similar in configuration to the layout depicted in FIG. 1A, above. As can be seen, the cold plate when installed completely covers the package 300, and so will compress each of the gaskets 302. The cold plate 304, in turn, is thermally coupled to a heat pipe 306. In typical installations, the cold plate 304 and heat pipe 306 are made from a heat-conductive metal, such as copper or aluminum. Owing to their metallic construction, the cold plate 304 and/or heat pipe 306 can act to radiate received RF energy, and may even amplify such energy depending upon their natural resonance frequencies, if not grounded. By contacting and compressing electrically conductive gaskets 302, which are attached to a ground in the package 300, the cold plate 304 and heat pipe 306 are also effectively grounded, thus providing a shield from emission of RF energy from the package 300.

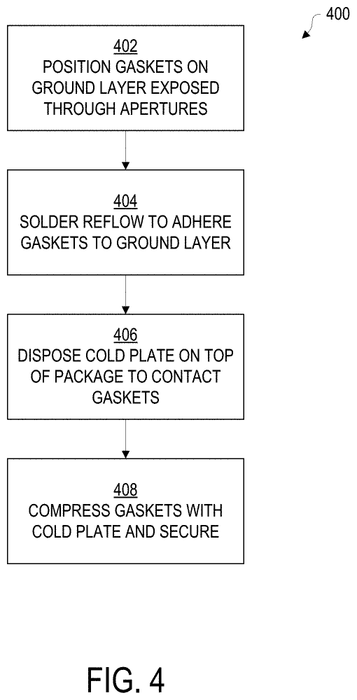

FIG. 4 illustrates the operations of a method 400 for creating an integrated circuit package that is RF shielded when a heat solution such as a heat sink or cold plate is installed onto the package. The operations of method 400 may be carried out in order or out of order, depending upon the needs of a specific implementation. Some operations may be omitted and/or other operations may be added, depending upon the specifics of a given embodiment.

In operation 402, electrically conductive compressible gaskets, such as gaskets 102, 122, 142, or 202, are placed in contact with a ground layer of an integrated circuit package. The contact may be made through corresponding apertures in an insulating or non-conductive layer on the surface of the package that exposes the conductive ground of the package. Each of the gaskets may have a foil layer or metal surface that contacts the ground layer. The foil layer or metal surface and/or the ground layer in each aperture may first be treated or coated with solder paste.

In operation 404, the gaskets are adhered to the ground layer, such as by soldering. Any suitable soldering technique may be employed, such as reflow or baking as may be used in securing SMT components. Where the gaskets are treated with solder paste, baking in an oven or using a hot air gun can cause the solder paste to melt and secure each gasket to the ground layer with a relatively solid and electrically conductive connection.

Operations 402 and 404, in embodiments, may be performed by the package manufacturer, with subsequent operations performed by a system installer or assembler who is deploying the package. In other embodiments, all operations of method 400 may be performed by a single party.

In operation 406, a cold plate or heat sink is disposed on top of the package such that it contacts both the package (or dies that protrude above the package substrate) as well as the gaskets. In packages that include stiffeners, the cold plate or heat sink may also contact the stiffener, depending upon the height of the stiffener relative to any dies. Furthermore, the dies and/or cold plate/heat sink may have a layer of thermally conductive compound first applied prior to placement, to enhance conduction of heat from the package to the cold plate or heat sink.

In operation 408, finally, pressure is applied to the cold plate or heat sink to bias it towards the package, thereby compressing the gaskets. The amount of pressure applied may depend on the specifics of a given implementation. In some embodiments, roughly 10 psi may be applied. Factors impacting the amount of pressure to be applied are ensuring good mechanical contact with the dies for transfer of heat, sufficient compression of the gaskets to ensure a good electrical connection, the structural rigidity of the package, and/or the structural rigidity of the heat sink or cold plate. Too high a pressure could cause the heat sink or cold plate to deform or otherwise distort, potentially compromising its mechanical connection to the die(s). Once the desired pressure has been achieved, the heat sink or cold plate may then be secured to the package to maintain the pressure and the gaskets under compression.

It will be apparent to those skilled in the art that various modifications and variations can be made in the disclosed embodiments of the disclosed device and associated methods without departing from the spirit or scope of the disclosure. Thus, it is intended that the present disclosure covers the modifications and variations of the embodiments disclosed above provided that the modifications and variations come within the scope of any claims and their equivalents.

### EXAMPLES

The following examples pertain to further embodiments.

Example 1 is an integrated circuit package, comprising a substrate comprised of a metallic ground layer; one or more dies disposed on the substrate; and a plurality of electrically conductive compressible gaskets; wherein individuals of the electrically conductive compressible gaskets are electrically bonded to the metallic ground layer, and are positioned to contact a plate and electrically ground the plate when the plate is secured to the package.

Example 2 includes the subject matter of example 1, or some other example herein, wherein the substrate is overlaid with a non-conductive layer, the non-conductive layer having a plurality of apertures, individuals of the plurality of gaskets placed in corresponding individuals of the plurality of apertures.

Example 3 includes the subject matter of example 1 or 2, or some other example herein, further comprising a stiffener disposed around a perimeter of the integrated circuit package and defining an interior space, wherein the plurality of electrically conductive compressible gaskets are located within the interior space.

Example 4 includes the subject matter of example 3, or some other example herein, wherein at least one of the plurality of electrically conductive compressible gaskets is in contact with the stiffener.

Example 5 includes the subject matter of any of examples 1-4, or some other example herein, wherein individuals of the electrically conductive compressible gaskets have dimensions of 1 mm width by 0.5 mm length by 0.4-0.5 mm height.

Example 6 includes the subject matter of any of examples 1-5, or some other example herein, wherein individuals of the electrically conductive compressible gaskets comprise a copper foil on a surface that contacts the metallic ground layer.

Example 7 includes the subject matter of any of examples 1-6, or some other example herein, wherein individuals of the electrically conductive compressible gaskets are soldered to the metallic ground layer.

Example 8 includes the subject matter of any of examples 1-7, or some other example herein, wherein the plurality of electrically conductive compressible gaskets comprises from four to six gaskets.

Example 9 is a system for EMI shielding of an integrated circuit package, comprising an integrated circuit package; and a plurality of electrically conductive compressible gaskets electrically bonded to a ground plane of the integrated circuit package and sized to contact a cold plate when the cold plate is disposed upon the integrated circuit package, wherein the cold plate is electrically connected to the ground plane when in contact with the plurality of electrically conductive compressible gaskets.

Example 10 includes the subject matter of example 9, or some other example herein, further comprising the cold plate disposed upon the integrated circuit package that compresses the plurality of electrically conductive compressible gaskets.

Example 11 includes the subject matter of example 10, or some other example herein, wherein individuals of the electrically conductive compressible gaskets are compressed from between 16% to 52% from their uncompressed height.

Example 12 includes the subject matter of example 10 or 11, or some other example herein, wherein the cold plate is biased towards the integrated circuit package at a pressure of 10 psi.

Example 13 includes the subject matter of any of examples 10-12, or some other example herein, wherein the cold plate has a plurality of recessed pockets corresponding to the plurality of electrically conductive compressible gaskets.

Example 14 includes the subject matter of any of examples 9-13, or some other example herein, wherein the system further comprises a laptop computer.

Example 15 includes the subject matter of any of examples 9-14, or some other example herein, further comprising a stiffener disposed upon the integrated circuit package that surrounds the plurality of electrically conductive compressible gaskets.

Example 16 is a method, comprising disposing a plurality of electrically conductive compressible gaskets upon a conductive ground layer of an integrated circuit package; disposing a cold plate upon a die of the integrated circuit such that the cold plate contacts the plurality of electrically conductive compressible gaskets and creates an electrically conductive path from the cold plate to the ground layer; and compressing, with the cold plate, the plurality of electrically conductive compressible gaskets.

Example 17 includes the subject matter of example 16, or some other example herein, further comprising soldering the plurality of electrically conductive compressible gaskets to the ground layer.

Example 18 includes the subject matter of example 17, or some other example herein, wherein soldering the plurality of electrically conductive compressible gaskets to the ground layer comprises applying solder to a copper foil disposed on a side of the plurality of electrically compressible gaskets.

Example 19 includes the subject matter of any of examples 16-18, or some other example herein, wherein disposing the plurality of electrically conductive compressible gaskets upon the ground layer comprises disposing the plurality of electrically conductive compressible gaskets within a plurality of apertures in an insulating layer that expose the ground layer.

Example 20 includes the subject matter of any of examples 16-19, or some other example herein, wherein compressing the plurality of electrically conductive compressible gaskets comprises compressing the plurality of electrically conductive compressible gaskets to between 16% to 52% of their uncompressed height.

Example 21 includes the subject matter of any of examples 16-20, or some other example herein, wherein compressing the plurality of electrically conductive compressible gaskets comprises compressing the cold plate onto the die of the integrated circuit to a pressure of 10 psi.

What is claimed is:

1. An integrated circuit package, comprising:
a substrate comprised of a metallic ground layer;
one or more dies disposed on the substrate; and
a plurality of electrically conductive compressible gaskets;
wherein individuals of the electrically conductive compressible gaskets are electrically bonded to the metallic ground layer, and are positioned to contact a plate and electrically ground the plate when the plate is secured to the package.

2. The package of claim 1, wherein the substrate is overlaid with a non-conductive layer, the non-conductive layer having a plurality of apertures, individuals of the plurality of gaskets placed in corresponding individuals of the plurality of apertures.

3. The package of claim 1, further comprising a stiffener disposed around a perimeter of the integrated circuit package and defining an interior space, wherein the plurality of electrically conductive compressible gaskets are located within the interior space.

4. The package of claim 3, wherein at least one of the plurality of electrically conductive compressible gaskets is in contact with the stiffener.

5. The package of claim 1, wherein individuals of the electrically conductive compressible gaskets have dimensions of 1 mm width by 0.5 mm length by 0.4-0.5 mm height.

6. The package of claim 1, wherein individuals of the electrically conductive compressible gaskets comprise a copper foil on a surface that contacts the metallic ground layer.

7. The package of claim 6, wherein individuals of the electrically conductive compressible gaskets are soldered to the metallic ground layer.

8. The package of claim 1, wherein the plurality of electrically conductive compressible gaskets comprises from four to six gaskets.

9. A system for EMI shielding of an integrated circuit package, comprising:
an integrated circuit package; and
a plurality of electrically conductive compressible gaskets electrically bonded to a ground plane of the integrated circuit package and sized to contact a cold plate when the cold plate is disposed upon the integrated circuit package,
wherein the cold plate is electrically connected to the ground plane when in contact with the plurality of electrically conductive compressible gaskets.

10. The system of claim 9, further comprising the cold plate disposed upon the integrated circuit package that compresses the plurality of electrically conductive compressible gaskets.

11. The system of claim 10, wherein individuals of the electrically conductive compressible gaskets are compressed from between 16% to 52% from their uncompressed height.

12. The system of claim 10, wherein the cold plate is biased towards the integrated circuit package at a pressure of 10 psi.

13. The system of claim 10, wherein the cold plate has a plurality of recessed pockets corresponding to the plurality of electrically conductive compressible gaskets.

14. The system of claim 10, wherein the system further comprises a laptop computer.

15. The system of claim 9, further comprising a stiffener disposed upon the integrated circuit package that surrounds the plurality of electrically conductive compressible gaskets.

16. A method, comprising:
disposing a plurality of electrically conductive compressible gaskets upon a conductive ground layer of an integrated circuit package;
disposing a cold plate upon a die of the integrated circuit such that the cold plate contacts the plurality of electrically conductive compressible gaskets and creates an electrically conductive path from the cold plate to the ground layer; and
compressing, with the cold plate, the plurality of electrically conductive compressible gaskets.

17. The method of claim 16, further comprising soldering the plurality of electrically conductive compressible gaskets to the ground layer.

18. The method of claim 17, wherein soldering the plurality of electrically conductive compressible gaskets to the ground layer comprises applying solder to a copper foil disposed on a side of the plurality of electrically compressible gaskets.

19. The method of claim 16, wherein disposing the plurality of electrically conductive compressible gaskets upon the ground layer comprises disposing the plurality of electrically conductive compressible gaskets within a plurality of apertures in an insulating layer that expose the ground layer.

20. The method of claim 16, wherein compressing the plurality of electrically conductive compressible gaskets comprises compressing the plurality of electrically conductive compressible gaskets to between 16% to 52% of their uncompressed height.

21. The method of claim 20, wherein compressing the plurality of electrically conductive compressible gaskets comprises compressing the cold plate onto the die of the integrated circuit to a pressure of 10 psi.
